(19) United States
(12) Patent Application Publication
(10) Pub. No.: US 2017/0250123 A1
(43) Pub. Date: Aug. 31, 2017

(54) Method and Apparatus for Cooling Integrated Circuits

(71) Applicant: Keysight Technologies, Inc., Minneapolis, MN (US)

(72) Inventors: Todd M. Bandhauer, Fort Collins, CO (US); Torben P. Grumstrup, Fort Collins, CO (US); David R. Hobby, Highlands Ranch, CO (US)

(73) Assignee: Keysight Technologies, Inc., Minneapolis, MN (US)

(21) Appl. No.: 15/056,847

(22) Filed: Feb. 29, 2016

(51) Int. Cl. H01L 23/473; H01L 23/467; F28F 23/00; F28D 15/00; F28F 13/08

(52) U.S. Cl. CPC H01L 23/4735; F28D 15/00; F28F 13/08; F28F 23/00; H01L 23/467; F28D 2021/0028

(57) ABSTRACT

An apparatus having first, second, and third chambers and a plurality of receiving channels is disclosed. The first chamber includes a device surface to be cooled. The second chamber has a first surface positioned opposite to the device surface to be cooled, the first surface including a plurality of jet openings adapted to spray a coolant on the device surface when the second chamber is pressured with the coolant. The third chamber is adapted to receive coolant that left the first chamber. Each of the receiving channels has a first end in the first chamber and a second end in the third chamber. Each of the receiving channels is adjacent to a corresponding one of the jet openings and is positioned to remove coolant dispersed into the first chamber by that jet opening.

### BACKGROUND OF THE INVENTION

Heat removal presents a significant obstacle that limits the performance of many semiconductor devices. For example, as clock rates are increased in central processing units, the heat that must be dissipated per unit time also increases. The heat is typically dissipated to the environment by moving the heat from a surface of the semiconductor device to the air. A fan and appropriate ducts can be used to direct air against a surface of the device. However, as heat dissipation requirements have increased, this solution has become inadequate. Increased heat dissipation is provided by solutions that utilize a heat pipe of some sort to move the heat from the limited area of the device surface to a larger area in which the heat can be transferred to the surrounding air more efficiently. In such schemes, the heat pipe has a small area that is pressed against a surface of the packaged semiconductor device, referred to as the heat pickup area, and a larger remote surface that provides increased area over which the heat can be transferred to the air, usually with the aid of a fan that blows air over the increased area. The latter area will be referred to as the heat dissipation area. Heat pipes constructed from solid metal such as copper are known. In addition, systems in which the heat pipe circulates water that flows over the heat pickup area and then runs through a remote radiator are also known. However, even these solutions are inadequate for many purposes.

Systems based on directing jets of a coolant at the surface to be cooled are also known. These systems can be grouped into two broad classes. The simplest systems direct a coolant that does not change phase when heated by the surface being cooled. Such systems are referred to as single phase systems, since the coolant does not change phase in the heat removal process. Single phase systems require only a pump and a radiator in addition to the nozzle array through which the jets are created. Unfortunately, single phase systems have not performed well because the spent liquid from one nozzle interferes with the flow from adjacent nozzles.

In two phase systems, the coolant changes phase during the heat transfer process. A liquid refrigerant is directed against the surface and is evaporated by the heat from the surface. The jets can be liquid or a mixture of droplets of the liquid imbedded in a gas flow that is directed at the surface to be cooled. Two phase systems can provide significantly more cooling capacity than single phase systems. In some two-phase systems, the generated vapor can be re-condensed in a heat exchanger before it is re-circulated as a liquid using a pump. These systems have similar complexity to single-phase systems, and, in multiple nozzle systems, their performance is also limited by the spent gas interfering with the flow from adjacent nozzles. In some cases, it may be advantageous to compress the gas prior to condensing it in a heat exchanger to lower the coolant temperature at the heat pickup region below the ambient temperature. However, these systems are considerably more complex, noisy, and costly.

### SUMMARY OF THE INVENTION

The present invention includes an apparatus having first, second, and third chambers and a plurality of receiving channels. The first chamber includes a device surface to be cooled. The second chamber has a first surface positioned opposite to the device surface to be cooled, the first surface including a plurality of jet openings adapted to spray a coolant on the device surface when the second chamber is pressured with the coolant. The third chamber is adapted to receive coolant that left the first chamber. Each of the receiving channels has a first end in the first chamber and a second end in the third chamber. Each of the receiving channels is adjacent to a corresponding one of the jet openings and is positioned to remove coolant dispersed into the first chamber by that jet opening.

In one aspect of the invention, there is a plurality of receiving channels associated with each of the jet openings, the receiving channels corresponding to that jet opening removing coolant sprayed into the first chamber by that jet opening without substantially interfering with the spray of coolant generated by others of the jet openings.

In another aspect of the invention, coolant dispersed by two of the jet openings returns through one of the receiving channels.

In another aspect of the invention, the apparatus includes an input port adapted to receive a coolant and direct that coolant into the second chamber and an output port adapted to remove coolant from the third chamber.

In a still further aspect of the invention, the device surface is a surface of a semiconductor die, the coolant being sprayed directly onto the surface of the semiconductor die. In a further aspect, the semiconductor die is enclosed by a package, and the first, second, and third chambers are part of the package.

In another aspect of the invention, the coolant is a dielectric, water, or a gas such as air.

In another aspect of the invention, the jet openings are characterized by a lateral density of jet openings per unit area on the first surface, and the device surface has areas of higher temperature. The jet openings are positioned such that a higher lateral density of jets are in the areas of higher temperature than in other areas on the device surface.

In another aspect of the invention, the apparatus includes a coolant reservoir and a pump for causing the coolant in the reservoir to flow through the input port and exit through the output port.

### BRIEF DESCRIPTION OF THE DRAWINGS

FIG. 1 illustrates a typical prior art heat transfer solution.

FIG. 2 is a cross-sectional view of the heat pickup region in a simple prior art single phase cooling system.

FIG. 3 illustrates a prior art embodiment that uses nozzles to direct the coolant.

FIG. 4 is a cross-sectional view of an embodiment of a cooling system according to the present invention.

FIG. 5 is a top cross-sectional view through line 5-5 shown in FIG. 4.

FIG. 6 illustrates another embodiment of a cooling system according to the present invention.

FIG. 7 illustrates a system 170 having an integrated circuit (IC) and a cooling arrangement according to one embodiment of the present invention.

FIG. 8 is a cross-sectional view of another embodiment of a cooling system according to the present invention.

### DETAILED DESCRIPTION OF THE PREFERRED EMBODIMENTS OF THE INVENTION

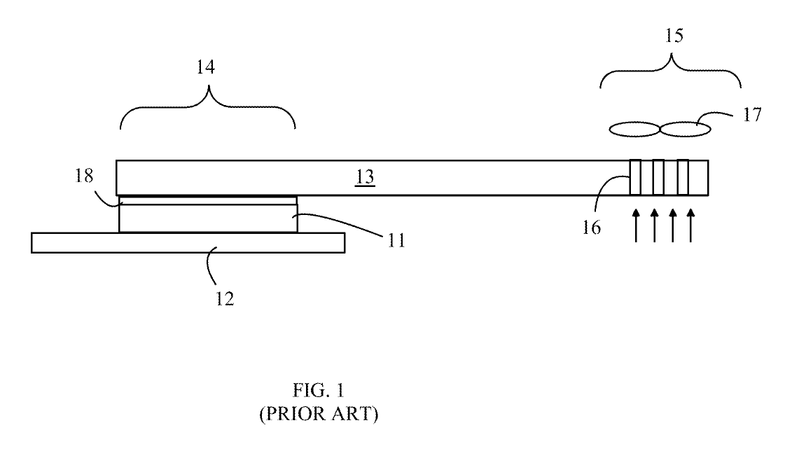

The manner in which the present invention provides its advantages can be more easily understood with reference to FIG. 1, which illustrates a typical prior art heat transfer solution. A packaged IC 11 is bonded to a printed circuit board 12 or similar substrate. A heat pipe 13 is attached to IC 11 by a layer of heat transfer interface material 18 in a heat pickup region 14. The heat is transferred by conduction or, in the case of a heat pipe, a combination of conduction and convection between the heat pipe working fluid to a heat dissipation region 15 that has a larger surface area than heat pickup region 14. A fan 17 forces air through or around heat dissipation region 15 which may include passages 16 to increase the transfer of the heat to the surrounding air. In some embodiments, heat pipe 13 includes a generated vapor that is pumped via capillary forces from heat pickup region 14 to heat dissipation region 15, where it is condensed and returned to the heat pickup region 14 as a liquid. The amount of heat that can be pumped from IC 11 depends on the thermal resistance of the heat path from the die in IC 11 to heat dissipation region 15 and the temperature difference between the die and ambient air that eventually receives the heat. In addition, in the case of a single phase heat system in which liquid is actively pumped through heat pickup region 14, the amount of heat that can be moved depends on the flow pattern of the liquid coolant over the surface being cooled.

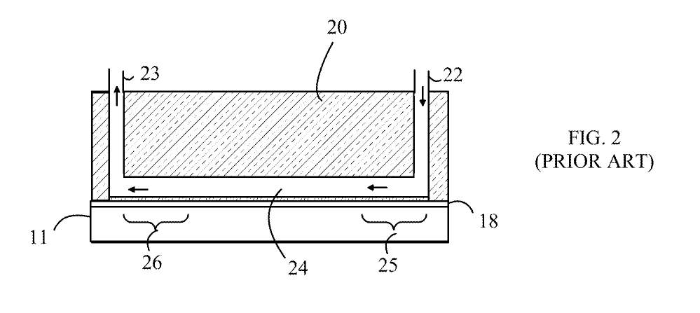

Refer now to FIG. 2, which is a cross-sectional view of the heat pickup region in a simple prior art single phase cooling system. An adapter 20 is attached to the IC with a layer of heat transfer interface material 18. The coolant, typically water, from a heat exchanger enters adapter 20 through an input port 22 and flows along the surface of adapter 20 that is in contact with the heat transfer medium through a chamber 24. The coolant is heated by the IC and leaves through an output port 23 and returns to the heat exchanger. As the liquid flows along chamber 24, it becomes heated, and hence, the amount of heat that can be transferred decreases along the coolant path. As a result, region 25 of IC 11 is cooled more than region 26. In addition, if the flow is laminar, most of the heat transfer takes place in the coolant layer adjacent to the bottom of chamber 24. The remaining layers of the flow receive less heat, and hence, are less efficient at removing heat.

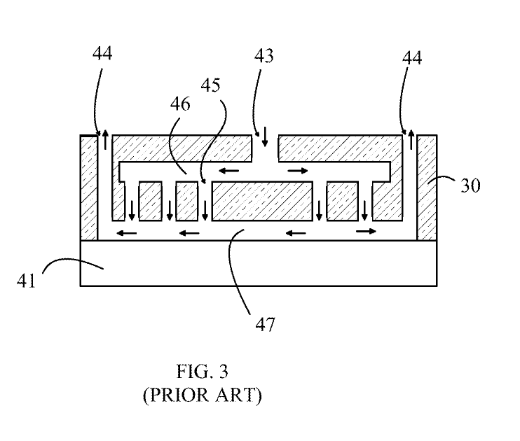

Prior art embodiments have attempted to solve these problems by using a plurality of nozzles to direct the coolant to the surface being cooled without requiring the flow pattern shown in FIG. 2. Refer now to FIG. 3, which illustrates a prior art embodiment that uses nozzles to direct the coolant. In this arrangement, an adapter 30 has an input port 43 that receives the coolant and directs the coolant into a chamber 46. The bottom of chamber 46 includes a plurality of openings 45 that direct jets of the coolant along the top surface of device 41, which is to be cooled. The spent coolant flows along the surface of device 41 in chamber 47 and exits through output ports 44. While this arrangement reduces the heat gradient discussed above, the spent coolant from one jet interferes with the adjacent jet. In addition, the adjacent jets discharge into the spent coolant flow, and hence, are inhibited from striking the surface to be cooled.

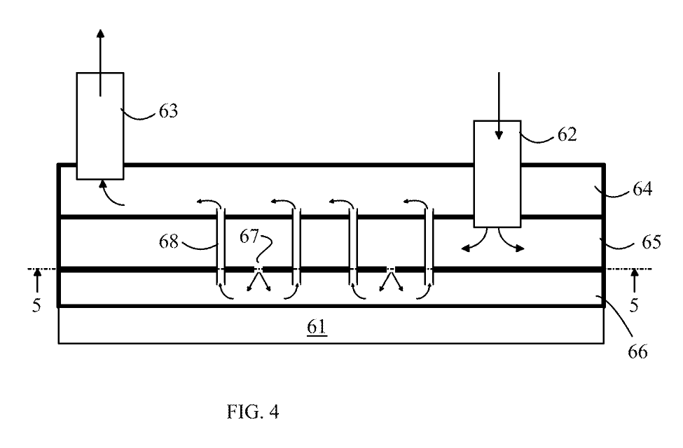

This lack of performance has limited the usefulness of single phase cooling systems. The present invention is based on the observation that the spent coolant from one jet must be collected in a manner that prevents that spent coolant from interfering with an adjacent jet. Refer now to FIG. 4, which is a cross-sectional view of an embodiment of a cooling system according to the present invention. The device to be cooled is shown at 61. Device 61 is cooled by coolant jets such as jet 67. The jets spray coolant into chamber 66 toward device 61. The spent coolant from each jet is collected by one or more coolant collection passages such as passage 68. The coolant collection passages move the coolant to coolant collection chamber 64, which, in turn, allows the heated coolant to exit through exit port 63. Coolant is supplied by an input port 62 that feeds the coolant into chamber 65 that supplies the jets. The coolant is supplied at a pressure such that the coolant is directed to the bottom surface of chamber 66, which is in thermal contact with device 61.

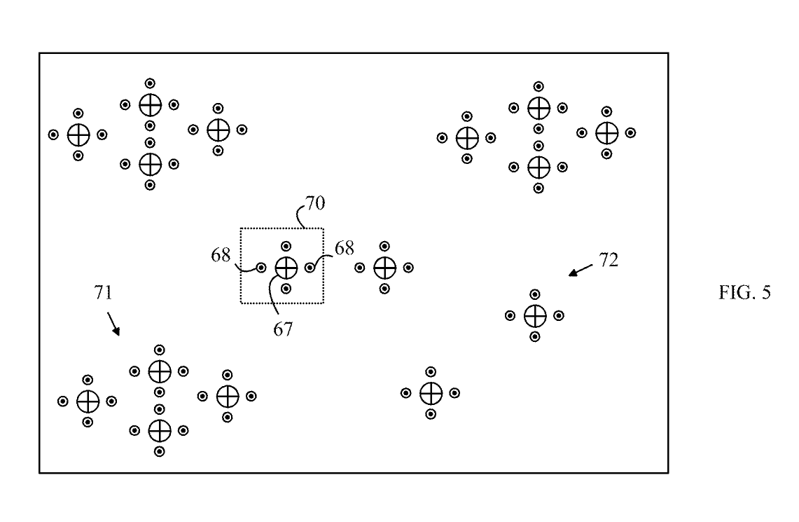

Refer now to FIG. 5, which is a top cross-sectional view through line 5-5 shown in FIG. 4. An exemplary jet assembly is shown at 70. Jet assembly 70 includes a jet 67 that directs the coolant toward the surface being cooled. In this case, that direction is into the paper. Jet assembly 70 also includes a plurality of return coolant collection passages 68. In this example, there are four return coolant collection passages for each jet 67; however, other numbers of return coolant collection passages could be utilized. The coolant collection passages are sized and distributed such that substantially all of the coolant that passes through the orifice in the jet assembly returns through the coolant collection passages in that jet assembly, and hence, the return flow does not interfere with other jet assemblies.

Since each jet assembly provides its own return path for the coolant, the density of jet assemblies can be varied according to the local need for cooling. Many ICs generate heat in a non-uniform manner that creates hot spots on the surface of the IC. By placing a higher density of jet assemblies over the hot spots, more effective cooling can be achieved than with a uniform distribution of jet assemblies. A more dense region of jet assemblies is shown at 71 in FIG. 5. Similarly, an area with less heat generation such as region 72 requires only one jet assembly.

The device being cooled in the above-described embodiments was a packaged IC in which the die is encapsulated in a hermetically sealed package that has a heat conducting surface that is mated to the adapter having the jet assemblies with a thermal interface material. The preferred coolant in this type of system is water because of its high specific heat and thermal conductivity. However, other coolants could be utilized.

If the IC generates more heat than this arrangement can transfer without subjecting the IC to temperatures in excess of its design limits, an arrangement in which the coolant is sprayed directly on the back surface of the die can be utilized, the circuitry being on the front surface of the die. In this case, a dielectric coolant is preferred. A significant fraction of that thermal resistance resides in the packaging material of IC 11 and the layer of transfer interface material 18. If a coolant could be applied directly to the backside of the die in IC 11, a significant portion of the thermal resistance is eliminated. However, the backside of the die is typically an electrical conductor or other material that cannot be brought in contact with water.

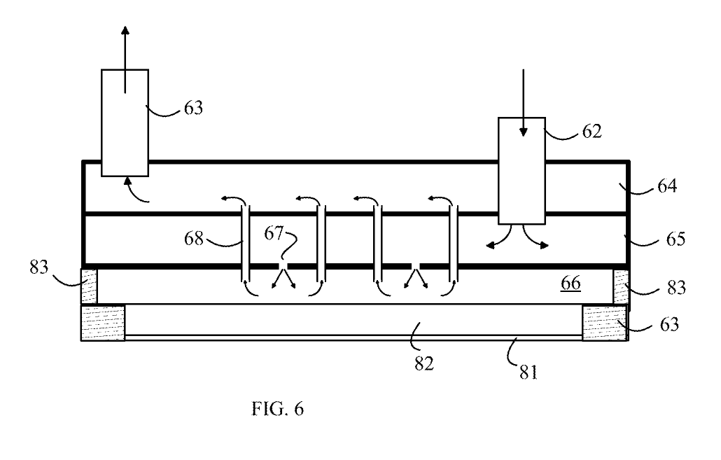

Refer now to FIG. 6, which illustrates another embodiment of a cooling system according to the present invention. In this embodiment, chamber 66 discussed above has been altered such that the bottom surface of chamber 66 is the top surface of die 82. The circuitry on die 82 is on front surface 81 together with the inter-connect pads for connecting that circuitry to an external substrate such as a printed circuit board. Die 82 is potted in a package 83 in which the back surface of the package has been removed or the package has been modified to lack a back surface over areas to be cooled. A cooling assembly according to the present invention is bonded to the back surface of the package with package 83 that set the height of chamber 66. A dielectric coolant is used for the coolant.

It should be noted that a cooling assembly according to the present invention could be attached to a die in the die packaging process. As noted above, in one aspect of the invention, the pattern of jet assemblies is customized to the die being cooled to provide more effective cooling. In this case, the cooling assembly is optimized for a particular die, and hence, the accommodations of scale in providing a generic assembly that can be used with a large number of different dies are not applicable. Attaching the cooling assembly at packaging also has the additional benefit of not processing the IC with the back surface of the die exposed under conditions that could result in contamination of the die.

In the above described embodiments, the coolant was a liquid dielectric medium. However, gaseous coolants can also be utilized. In particular, compressed air could be used as the coolant. Air is particularly attractive as a coolant in that the heated air can be vented to the surrounding environment without the need to recompress the air. In addition, small leaks can be tolerated.

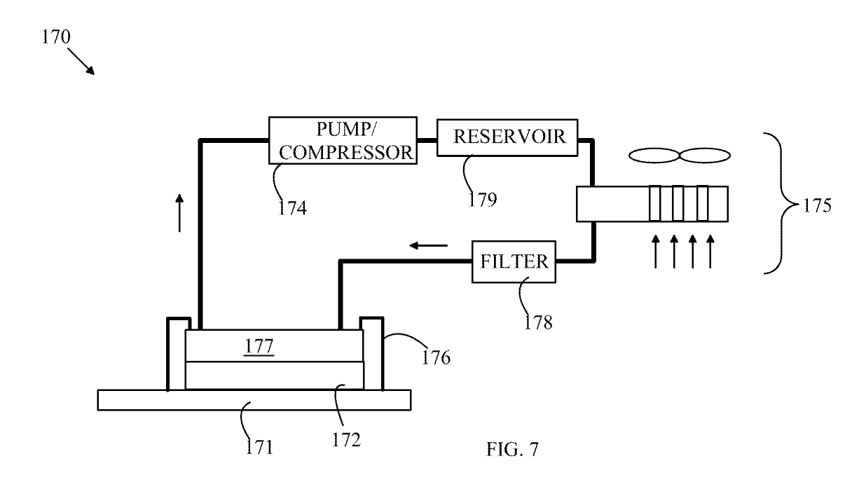

Refer now to FIG. 7, which illustrates a system 170 having an IC and a cooling arrangement according to one embodiment of the present invention. IC 172 is connected to a printed circuit board 171 which includes clamps 176 that force a cooling device 177 according to the present invention against IC 172 so as to seal the cover of cooling device 177 against IC 172. A pump/compressor circulates coolant between cooling device 177 and a radiator 175. An optional reservoir 179 can be used to increase the amount of coolant available for circulation. An optional filter 178 removes any particulate material from the coolant that could clog the passageways in cooling device 177. As noted above, cooling device 177 directs the coolant against a surface of IC 172. The surface is preferably a surface of a die within IC 172; however, as noted above, the surface could be the outer package of IC 172.

In embodiments in which the coolant is air, the return path from cooling device 177 to the pump can be omitted. In this case the, heated air is merely vented to the environment at a location remote from cooling device 177 or other circuitry that would be adversely impacted by the warm air. Depending on the pressure of the air leaving pump/compressor 174, radiator 175 could also be omitted. If the pressure of the air is sufficient to cause significant heating of the air leaving pump/compressor 174, radiator 175 is preferred.

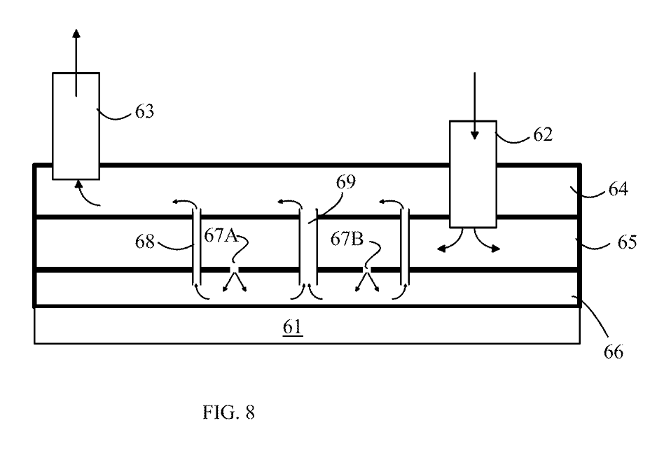

In the above-described embodiments, there are one or more return coolant paths for each jet. However, embodiments in which multiple jets utilize the same coolant path can also be constructed provided the flow of the heated coolant from each jet does not interfere with the unheated coolant being dispensed by the other jets. Refer now to FIG. 8, which is a cross-section of another embodiment of a cooling system according to the present invention. The cooling system in FIG. 8 is similar to the cooling system shown in FIG. 4, and hence, elements that perform analogous functions have been given the same numerical designations. The cooling system in FIG. 8 differs from that shown in FIG. 4 in that jets 67A and 67B share a coolant return path 69. Coolant return path 69 is positioned such that heated coolant from jet 67A does not substantially mix with coolant from jet 67B prior to the coolant striking the surface of device 61.

For the purposes of the present discussion, the warm coolant from a first jet is defined to substantially interfere with the spray of coolant from a second jet if the warm coolant from the first jet reduces the cooling provided by the second jet by more than 50 percent of the cooling that would occur absent the first jet.

The above-described embodiments of the present invention have been provided to illustrate various aspects of the invention. However, it is to be understood that different aspects of the present invention that are shown in different specific embodiments can be combined to provide other embodiments of the present invention. In addition, various modifications to the present invention will become apparent from the foregoing description and accompanying drawings. Accordingly, the present invention is to be limited solely by the scope of the following claims.

1. An apparatus comprising:
a first chamber comprising a device surface to be cooled;
a second chamber having a first surface positioned opposite to said device surface to be cooled, said first surface comprising a plurality of jet openings adapted to spray a coolant on said device surface when said second chamber is pressured with said coolant;
a third chamber adapted to receive coolant that left said first chamber; and
a plurality of receiving channels, each of said plurality of receiving channels having a first end in said first chamber and a second end in said third chamber, each of said plurality of receiving channels being adjacent to a corresponding one of said plurality of jet openings and being positioned to remove coolant dispersed into said first chamber by that jet opening, wherein said coolant does not change phase on contact with said device surface.

2. The apparatus of claim 1 comprising a plurality of said receiving channels associated with one of said jet openings, said receiving channels corresponding to said one of said plurality of jet opening removing said coolant sprayed into said first chamber by that one of said plurality of jet openings without substantially interfering with said coolant sprayed by others of said plurality of jet openings.

3. The apparatus of claim 1 wherein coolant dispersed by two of said plurality of jet openings returns through one of said receiving channels.

4. The apparatus of claim 1 further comprising:
an input port adapted to receive a coolant and direct that coolant into said second chamber; and
an output port adapted to remove coolant from said third chamber.

5. The apparatus of claim 1 wherein said device surface is a surface of a semiconductor die, said coolant being sprayed directly onto said surface of said semiconductor die.

6. The apparatus of claim 5 wherein said coolant is a dielectric.

7. The apparatus of claim 5 wherein said semiconductor die is enclosed by a package and wherein said first, second, and third chambers are part of said package.

8. The apparatus of claim 1 wherein said coolant is water.

9. The apparatus of claim 1 wherein said coolant is a gas.

10. The apparatus of claim 9 wherein said gas is air.

11. The apparatus of claim 1 wherein said jet openings are characterized by a lateral density of jet openings per unit area on said first surface and wherein said device surface has areas of higher temperature, said jet openings having a higher lateral density in said areas of higher temperature than in other areas on said device surface.

12. The apparatus of claim 4 further comprising a coolant reservoir and a pump for causing said coolant in said reservoir to flow through said input port and exit through said output port.
